(19) United States
(12) Patent Application Publication
(10) Pub. No.: US 2014/0257715 A1
(43) Pub. Date: Sep. 11, 2014

(54) Robust Power Flow Methodologies for Distribution Networks with Distributed Generators

(71) Applicant: BIGWOOD TECHNOLOGY, INC., Ithaca, NY (US)

(72) Inventors: Hsiao-Dong Chiang, Ithaca, NY (US); Yong Tang, Beijing (CN); Tian-Qi Zhao, Tianjin (CN); Jiao-Jiao Deng, Tianjin (CN); Hao Sheng, Tianjin (CN); Yi Wang, Beijing (CN); Jun-Xian Hou, Beijing (CN)

(73) Assignee: BIGWOOD TECHNOLOGY, INC., Ithaca, NY (US)

(21) Appl. No.: 13/791,977

(22) Filed: Mar. 9, 2013

(51) Int. Cl. G01R 21/133; G06F 17/11

(52) U.S. Cl. CPC G01R 21/133; G06F 17/11
USPC 702/34

(57) ABSTRACT

A method predicts power flow in a distributed generation network of at least one distributed generator and at least one co-generator, where the network is defined by a plurality of network nonlinear equations. The method includes applying an iterative method to the plurality of network nonlinear equations to achieve a divergence from a power flow solution to the plurality of network nonlinear equations. The method also includes applying the iterative method to find a first solution to a plurality of simplified nonlinear equations homotopically related by parameterized power flow equations to the plurality of network nonlinear equations. The method further includes iteratively applying the iterative method to the parameterized power flow equations starting with the first solution to achieve the power flow solution to the plurality of network nonlinear equations.

### BACKGROUND OF THE INVENTION

1. Field of the Invention

The invention pertains to the field of large-scale, unbalanced, power-distribution networks. More particularly, the invention pertains to robust methodologies for solving power flow equations of unbalanced power distribution networks with distributed generators.

2. Description of Related Art

Recent years have witnessed a growing trend towards the development and deployment of distributed generation or dispersed generation (DG). This trend in combination with the emergence of a number of new distribution generation technologies has profoundly changed the traditional paradigm of the power industry in distribution networks. The widespread use of dispersed generations in utility distribution feeders is more and more likely in the near future. With this tendency, it is necessary to develop analysis tools for assessment of the impacts of dispersed generations on the steady-state of distribution networks. One challenging task for the steady-state analysis of distribution networks with DGs is the issue of power flow convergence in power flow studies. Indeed, these power flow solution algorithms typically have good convergence properties when applied to distribution networks with dispersed generations modeled as P-Q (fixed power) nodes, but they encounter divergence in power flow study when the dispersed generations are modeled as P-V (fixed voltage) nodes. Hence, there is a pressing need for the development of a reliable and effective method for power flow study of distribution networks with dispersed generations.

Recent years have witnessed a growing trend towards the development and deployment of distributed generation (DG) due to government policy changes, the increased availability of small-scale generation technologies, and environment impact concerns. However, adding DGs to distribution networks imposes significant changes on operating conditions such as reverse power flow, voltage rise, increased fault levels, reduced power losses, island mode operation, harmonic problem, and stability problem. To evaluate these significant changes, detailed analysis of distribution networks with DGs is necessary. One important detailed analysis is the steady-state analysis of distribution networks with DGs.

With this tendency, it is necessary to develop analysis tools for evaluating the impacts of dispersed generations on the steady-state of distribution networks. Voltage violations due to the presence of DGs can considerably limit the amount of power supplied by these DGs. Before installing or allowing the installation of a DG, utility engineers must analyze the worst case operating scenario in order to ensure that the network voltages will not be adversely affected by the DGs by performing power flow studies. In order to determine the maximum number of DGs that can be installed without steady-state voltage violations, the network voltages are calculated using a power flow solver.

However, one challenging task is the issue of power flow divergence when it is applied to distribution networks with dispersed generations. Indeed, many power flow solvers typically have good convergence properties when applied to distribution networks with dispersed generations modeled as P-Q nodes, while they encounter divergence in the power flow studies when dispersed generations are modeled as P-V nodes. On the other hand, it is more appropriate to model DGs as P-V nodes instead of P-Q nodes. Hence, there is a critical and pressing need for the development of a reliable method for power flow study for analyzing distribution networks with dispersed generations. A high penetration of DGs in the distribution network generally makes the task of planning and operation of distribution networks more complex.

Many DG installations employ induction and synchronous machines. Usually, synchronous generators connected to distribution networks are operated as constant real power sources and they do not participate at system frequency control. There are in fact two modes of controlling the excitation system of distributed synchronous generators. One mode is to maintain the constant terminal voltage (voltage control mode) and the other mode is to maintain the constant power factor. The constant power factor mode is usually adopted by independent power producers to maximize the real power production. Hence, depending on the contract and control status, a DG may be operated in one of the following modes:

1) In “parallel operation” with the feeder, i.e., the generator is located near and designated to supply a large load with fixed real and reactive power output. The net effect is the reduced load at a particular location.

2) To output power at a specified power factor.

3) To output power at a specified terminal voltage.

The nodes with DGs in the first two cases can be well represented as P-Q nodes while a generation node in the third case must be modeled as a P-V node. If the required reactive generation for a dispersed generation (to support the specified voltage) is beyond its reactive generation capability, then the reactive generation of the dispersed generation is set to its limit and the dispersed generation is modeled as a P-Q unit.

With the modeling of dispersed generation as the P-Q model, the general-purpose solution methods designed for traditional distribution networks are still applicable with minor modifications. However, when some dispersed generations are modeled as devices which deliver a specified real power while maintaining a given voltage magnitude, i.e. the typical P-V bus used for generator buses in transmission systems, then the general-purpose distribution power flow methods may encounter severe convergence problems.

All the solution algorithms developed in the last 15 years typically have good convergence properties when applied to distribution networks with DGs modeled as P-Q nodes. However, some of these solution algorithms encounter the divergence issue in power flow study when DGs are modeled as P-V nodes. Descriptions of this difficulty of divergence associated with distribution networks with P-V buses and loops have been well documented in the literature.

Chiang and Baran (“On the existence and uniqueness of load flow solution for radial distribution power networks”, IEEE Transactions on Circuits and Systems, Vol. 37, pp. 410-416, 1990) disclose a load flow solution with feasible voltage magnitude for radial distribution networks always existing and being unique.

Miu and Chiang (“Existence, uniqueness, and monotonic properties of the feasible power flow solution for radial three-phase distribution networks”, IEEE Transactions on Circuits and Systems I: Fundamental Theory and Applications, Vol. 47, pp. 1502-1514, 2000) disclose a three-phase power flow solution with feasible voltage magnitude for radial three-phase distribution networks with nonlinear load modeling always existing and being unique.

Zimmerman (“Comprehensive Distribution Power Flow: Modeling, Formulation, Solution Algorithms and Analysis,” Ph.D Dissertation, Cornell University, January 1995) discloses formulations and efficient solution algorithms for the distribution power flow problem, which takes into account the detailed and extensive modeling necessary for use in the distribution automation environment of a real world electric power distribution system.

Chen et al. (“Distribution System Power Flow Analysis-a Rigid Approach”, IEEE Trans. on Power Delivery, Vol. 6, pp. 1146-1152, 1991) discloses an approach oriented toward applications in three phase distribution system operational analysis rather than planning analysis.

Zhu and Tomsovic (“Adaptive Power Flow Method for Distribution Systems with Dispersed Generation”, IEEE Trans. on Power Delivery, Vol. 17, No. 3, July 2002, pp. 822-827) disclose a proposed adaptive compensation-based power flow method that is fast and reliable while maintaining necessary accuracy.

The above-mentioned references are hereby incorporated by reference herein.

### SUMMARY OF THE INVENTION

A method predicts the power flow in a distributed generation network of at least one distributed generator and at least one co-generator, where the network is defined by a plurality of network nonlinear equations. The method includes applying an iterative method to the plurality of network nonlinear equations to achieve a divergence from a power flow solution to the plurality of network nonlinear equations. The method also includes applying the iterative method to find a first solution to a plurality of simplified nonlinear equations homotopically related by parameterized power flow equations to the plurality of network nonlinear equations. The method further includes iteratively applying the iterative method to the parameterized power flow equations starting with the first solution to achieve the power flow solution to the plurality of network nonlinear equations. In some embodiments, the iterative method is an Implicit Z-Bus Gauss method. In other embodiments, the iterative method is Newton's method.

### BRIEF DESCRIPTION OF THE DRAWINGS

FIG. 1 shows voltage mismatches on node #633 versus the number of iterations on the modified IEEE 13-bus system.

FIG. 2 shows a comparison of voltage profiles of a Phase A IEEE 13-bus system with a P-Q model and with a P-V model of node #633.

FIG. 3 shows voltage mismatches on node #21 versus the number of iterations on the modified IEEE 123-bus system.

FIG. 4 shows voltage mismatches on node #1378 versus the number of iterations on the 1101-node system.

FIG. 5 shows a comparison of Voltage Profiles of Phase A of practical 1101-node System with the P-Q model and with P-V model of 1 P-V node in the system.

FIG. 6 shows a comparison of voltage profiles of Phase A of IEEE 8500-node System under the P-Q model and P-V model of 10 P-V nodes in the system.

### DETAILED DESCRIPTION OF THE INVENTION

In the present methods, the power flow problem of general distribution network with DGs modeled as P-V, or P-Q, or P-Q(V) buses is addressed. In the present methods, robust solution methods are used for general distribution networks with DGs modeled as P-V buses.

In some embodiments, the present methods are automated. At least one computation of the present methods is performed by a computer. Preferably all of the computations in the present methods are performed by a computer. A computer, as used herein, may refer to any apparatus capable of automatically carrying out computations base on predetermined instructions in a predetermined code, including, but not limited to, a computer program.

The present methods are preferably robust methods for power flow study for practical distribution networks with dispersed generations. The robust methods are preferably developed with the following goals in mind:

1) The methods are easily implemented in the framework of current distribution power flow methods. They are preferably easily implemented in the framework of current three-phase distribution power flow programs.

2) The methods are applicable to distribution networks consisting of a three-phase source supplying power through single-, two-, or three-phase distribution lines, switches, shunt capacitors, voltage regulators, co-generators, DGs, and transformers to a set of nodes with a given load demand.

3) The methods have sound theoretical basis.

4) The methods are applicable to large-scale distribution networks.

From an implementation viewpoint, goal 1) requires that the robust power flow method is easily integrated into the existing power flow packages. From a modeling viewpoint, goal 2) requires that the robust power flow method deal with all the elements and devices in practical distribution networks. From a robust viewpoint, goal 3) requires that the robust power flow method has the global convergence property. From a practical viewpoint, goal 4) requires that the robust power flow method is applicable to large-scale distribution networks.

In the present methods, a three-stage robust power flow methodology has been developed. A design goal of this methodology is to enhance a power flow method (solver) for solving general distribution networks with DGs. Hence, the present methods preferably assist existing power flow solvers to be more robust in solving distribution networks with DGs.

The set of power flow equations describing general distribution networks with DGs modeled as P-V node are preferably the following:

F(x)=0 [1]

The set of easy power flow equations describing general distribution networks with DGs modeled as P-Q node is preferably:

G(x)=0 [2]

In the present methods, homotopy methods, sometimes called embedding path-following methods, are preferably applied to solve a system of nonlinear algebraic equations [1]. The idea behind homotopy methods is to construct a parameterized system of equations, such that the parameterized system of equations at λ=0 is easy to solve and the parameterized system of equations at λ=1 is identical to the difficult problem. The homotopy function (or equations) gives a continuous deformation between the easy problem and the problem of interest. The homotopy function represents a set of n nonlinear equations with n+1 unknowns. From a computational viewpoint, homotopy methods can then be viewed as tracing an implicitly defined curve (through a solution space) from a starting point, which is a solution of the easy problem, to an unknown solution of the difficult problem [1]. If a solution of the difficult problem [1] is obtained, this procedure is successful.

To solve a difficult problem [1], an appropriate easy problem [2] is devised, which is easier to solve or has one or more known solutions. Homotopy methods entail embedding a continuation parameter into the difficult problem [1] to form a homotopy function of a higher-dimensional set of nonlinear equations:

H(x,λ):Rⁿ×R→Rⁿ,xεRⁿ [3]

which satisfy the following two boundary conditions:

H(x,0)=G(x) [3a]

H(x,1)=F(x) [3b]

A three-stage robust power flow methodology is presented as follows:
Stage I: Apply a conventional power flow method to solve the power flow equations [1]. The conventional power flow method is preferably an iterative method. In some embodiments, the conventional power flow method is the Implicit Z-bus Gauss method. In other embodiments, the conventional power flow method is Newton's method. If the method converges to a solution, then stop. Otherwise, go to Stage II.
Stage II: Apply the power flow method of Stage I to solve the simple power flow equations [2]. Let the solution be 0.7.
Stage III: Form the parameterized power flow equation [3] and apply the power flow method to iteratively solve the equation [3] starting from the power flow solution obtained in Stage II until the parameterized power flow equation [3] becomes the power flow equations [1] by varying the parameter value from zero to one.

In a preferred embodiment, a continuation method is used to implement Stage III. In a preferred embodiment, the power flow method used at Stage I is also used as the corrector in the continuation method.

Since the Implicit Z-Bus Gauss method (see, for example, Sun et al., “Calculation of Energy Losses in a Distribution System”, IEEE Transactions on Power Apparatus and Systems, Vol. PAS-99, pp. 1347-1356, 1980) and Newton's method (see, for example, Tinney and Hart, “Power Flow Solution by Newton's Method”, IEEE Transactions on Power Apparatus and Systems, Vol. PAS-86, pp. 1449-1460, 1967) are two of the most popular methods for solving general distribution network, they are applied in the next two sections to illustrate the robust power flow methodology of the present invention.

The above-mentioned references are hereby incorporated by reference herein.

### Homotopy-Enhanced Implicit Z-Bus Gauss Method

The following set of power flow equations are used for represented general distribution networks with DGs and co-generators modeled as P-V buses:

I=Y_{bus}V [4]

where the vector V is node voltages, the vector I is nodal current injection, and Y_{bus} is the nodal admittance matrix for the network containing all constant Z elements, including constant Z loads. The collection of network buses is partitioned into source (1), P-V buses (such as co-generators and DGs) (2), and remaining buses (3):

$$[ \begin{matrix}{I}_{1} \\ {I}_{2} \\ {I}_{3}\end{matrix} ] = [ \begin{matrix}{Y}_{11} & {Y}_{12} & {Y}_{13} \\ {Y}_{21} & {Y}_{22} & {Y}_{23} \\ {Y}_{31} & {Y}_{32} & {Y}_{33}\end{matrix} ] [ \begin{matrix}{V}_{1} \\ {V}_{2} \\ {V}_{3}\end{matrix} ] \qquad [ 5 ]$$

### Case 1: No Constant Power Device

If the network contains no constant power device components, then I₃ is a known constant injection, and V₃ is found directly from the following:

V₃=Y₃₃⁻¹(I₃−Y₃₁V₁−Y₃₂V₂) [6]

This is a direct solution using a nodal method for linear circuits.

### Case 2: Constant Power Device

If the network has constant S components, then these elements are linearized by replacing them with equivalent current injections based on an estimate of the bus voltages. In this case, I₃ is a function of V₃:

V₃=Y₃₃⁻¹(I₃(V₃)−Y₃₁V₁−Y₃₂V₂) [7]

The Gauss method is applied to solve equation [7] by repeatedly updating V₃, evaluating the right hand side using the most recent value of V₂. When the change in V₃ between iterations becomes smaller than a predetermined tolerance, the solution has been obtained. Hence, the solution strategy is to replace non-linear elements (constant S) with linear equivalents (current injection) at present voltage and then solve for voltages directly using a nodal method for linear circuits.

A robust 3-stage method for power flow study for distribution networks with DGs and co-generators modeled as P-V buses preferably proceeds by the following stages. Stage I aims to solve the power flow equations with DGs and co-generators modeled as P-V buses. As is well known, Stage I may encounter divergence problems. Stage II solves the power flow equations with DGs and co-generators modeled as P-Q buses. A preferred method, Implicit Gauss method, solves this type of problems reliably. A homotopy procedure is preferably used in Stage III so that the power flow equations with DGs and co-generators modeled as P-V buses are ‘eventually’ solved, starting from the power flow solution obtained in Stage II method. The computational scheme for implementing Stage III is a continuation method.

### Stage I

1) Form Y_{bus} for the power flow equations.
2) Partition Y_{bus} into Y₁₁, Y₁₂, Y₁₃, Y₂₁, Y₂₂, Y₂₃, Y₃₁, Y₃₂, Y₃₃.
3) Factor

$$[ \begin{matrix}{Y}_{22} & {Y}_{23} \\ {Y}_{32} & {Y}_{33}\end{matrix} ]$$

into triangular factors L and U.
4) Compute current I₃ injected by constant I and constant S components based on current value of V₃. For the P-V node, current I₂ is updated through bus equations

$${Q}_{i} = Im \{ {V}_{i}^{*} {\sum }_{j = 1}^{m} {Y}_{ij} {V}_{j} \} ;$$

$${I}_{i} = \frac{{P}_{i} - j {Q}_{i}}{{V}_{i}^{*}} .$$

5) Solve

$$Ly = [ \begin{matrix}{I}_{2} \\ {I}_{3} ( {V}_{3} )\end{matrix} ] - [ \begin{matrix}{Y}_{21} \\ {Y}_{31}\end{matrix} ] {V}_{1}$$

for y via forward substitution.
6) Solve

$$U [ \begin{matrix}{V}_{2} \\ {V}_{3}\end{matrix} ] = y$$

for

$$[ \begin{matrix}{V}_{2} \\ {V}_{3}\end{matrix} ]$$

via backward substitution. For the P-V node, maintain the voltage magnitude at a specified value

$${V}_{i} = \frac{{V}_{i}}{\vert {V}_{i} \vert} \cdot \vert {V}_{( spec )} \vert .$$

7) If the change in

$$[ \begin{matrix}{V}_{2} \\ {V}_{3}\end{matrix} ]$$

is greater than a predetermined tolerance, go to step 4).

Otherwise, terminate Stage 1.

It is known that Stage I may not converge, especially when multiple DGs that are modeled as P-V buses are present. In such a case, the method proceeds with Stage II and Stage III when Stage I of the three-stage method is unable to solve the underlying problem. In Stage II, all the P-V buses related to V₂ are treated as P-Q buses, and these buses related to V₂ are ‘homotopized’ into P-V buses in Stage III. The Implicit Gauss method is highly robust in solving the three-phase power flow equations in Stage II.

### Stage II

8) Factor

$$[ \begin{matrix}{Y}_{22} & {Y}_{23} \\ {Y}_{32} & {Y}_{33}\end{matrix} ]$$

into the triangular factors L and U for the simple power flow equations.
9) Compute the current I₃ injected by constant I and constant S components based on the current value of V₃.
10) Solve

$$Ly = [ \begin{matrix}{I}_{2} \\ {I}_{3} ( {V}_{3} )\end{matrix} ] - [ \begin{matrix}{Y}_{21} \\ {Y}_{31}\end{matrix} ] {V}_{1}$$

for y via forward substitution.

11) Solve

$$U [ \begin{matrix}{V}_{2} \\ {V}_{3}\end{matrix} ] = y$$

for

$$[ \begin{matrix}{V}_{2} \\ {V}_{3}\end{matrix} ]$$

via backward substitution.
12) If the change in

$$[ \begin{matrix}{V}_{2} \\ {V}_{3}\end{matrix} ]$$

is greater than a predetermined tolerance, go to step 9).
Otherwise, terminate Stage II.

The resulting solution of V₂ is denoted as V_{2(P-Q)}, which indicates that the solution are being obtained under the condition that DGs are modeled as P-Q buses. V_{2(spec)} is the voltage magnitude vector specified at the P-V buses. Stage III aims to reliably compute a power flow solution with V₂ equal to V_{2(spec)}. In other words, Stage III of the integrated method contains a procedure for obtaining a power flow solution achieving V₂ equal to V_{2(spec)}.

The following parameterized vector is first defined:

V₂(λ)=λV_{2(spec)}+(1−λ)V_{2(P-Q)} [8]

The following parameterized power flow equations are then formed:

$$[ \begin{matrix}{I}_{1} \\ {I}_{2} \\ {I}_{3}\end{matrix} ] = [ \begin{matrix}{Y}_{11} & {Y}_{12} & {Y}_{13} \\ {Y}_{21} & {Y}_{22} & {Y}_{23} \\ {Y}_{31} & {Y}_{32} & {Y}_{33}\end{matrix} ] [ \begin{matrix}{V}_{1} \\ {V}_{2} ( λ ) \\ {V}_{3}\end{matrix} ] \qquad [ 9 ]$$

Regarding the parameterized power flow equations [8]:
For λ=0, V₂(λ)=V_{2(P-Q)}, the parameterized power flow equations [8] equals the power flow equations [5] with all the DGs and co-generators being modeled as P-Q buses, whose power flow solution is solved by Stage II.
For λ=1, V₂(λ)=V_{2(spec)}, the parameterized power flow equations [8] equals the power flow equations [5] with all the DGs and co-generators being modeled as P-V buses, whose power flow solution is solved by Stage I.

### Stage III

13) Determine the partition Δλ and use V_{2(P-Q)} obtained in Stage II as the initial guess.
14) Set λ and save the converged voltage and reactive power. Terminate the procedure and output the power flow solution if |V−V_{(spec)}| is less than a predetermined tolerance. Otherwise, go to step 15).
15) For the bus modeled as a P-V bus, compute the current injected by the following parameterized vector:

I₂=λI_{2(spec)}+(1−λ)I_{2(P-Q)}
where

$${I}_{2 ( P - Q )} = \frac{P - j {Q}_{( P - Q )}}{{V}_{2 ( P - Q )}^{*}} ; {I}_{2 ( spec )} = \frac{P - j {Q}^{′}}{{V}_{2 ( spec )}^{*}} .$$

For I_{2(spec)}, Q′ is calculated by

$${S}_{i}^{′} = P + j {Q}^{′} = {V}_{i} {\sum }_{j ∈ i} {Y}_{ij}^{*} {V}_{j}^{*} .$$

16) Solve

$$Ly = [ \begin{matrix}{I}_{2} \\ {I}_{3} ( {V}_{3} )\end{matrix} ] - [ \begin{matrix}{Y}_{21} \\ {Y}_{31}\end{matrix} ] {V}_{1}$$

for y via forward substitution.

17) Solve

$$U [ \begin{matrix}{V}_{2} \\ {V}_{3}\end{matrix} ] = y$$

for

$$[ \begin{matrix}{V}_{2} \\ {V}_{3}\end{matrix} ]$$

via backward substitution.
18) If the change in

$$[ \begin{matrix}{V}_{2} \\ {V}_{3}\end{matrix} ]$$

is less than a predetermined tolerance, go to step 14).
Otherwise, update the parameter 2, and set the voltage vector as V₂=λV_{2(spec)}+(1−λ)V₂ and go to step 15).

Both the implicit Z-bus Gauss method and the present homotopy-enhanced implicit Z-bus Gauss method were applied to the following standard test systems for illustrative purposes:

1) an IEEE 13-bus test system

2) an IEEE 123-bus test system

3) an IEEE 8,500-node test system

4) a practical 1101-node distribution network.

For each of the test systems, the popular prior art implicit Z-bus Gauss method fails in several cases, while the present homotopy-enhanced implicit Z-bus Gauss method succeeds in obtaining the power flow solution in all cases.

The convergence criteria used in each of the four test systems are the following:
1) The power flow convergence criterion is 10⁻⁷ for the voltage magnitude of each node.
2) The homotopy procedure convergence criterion is 10⁻⁴ in voltage magnitude at every P-V node.

### IEEE 13-Bus System

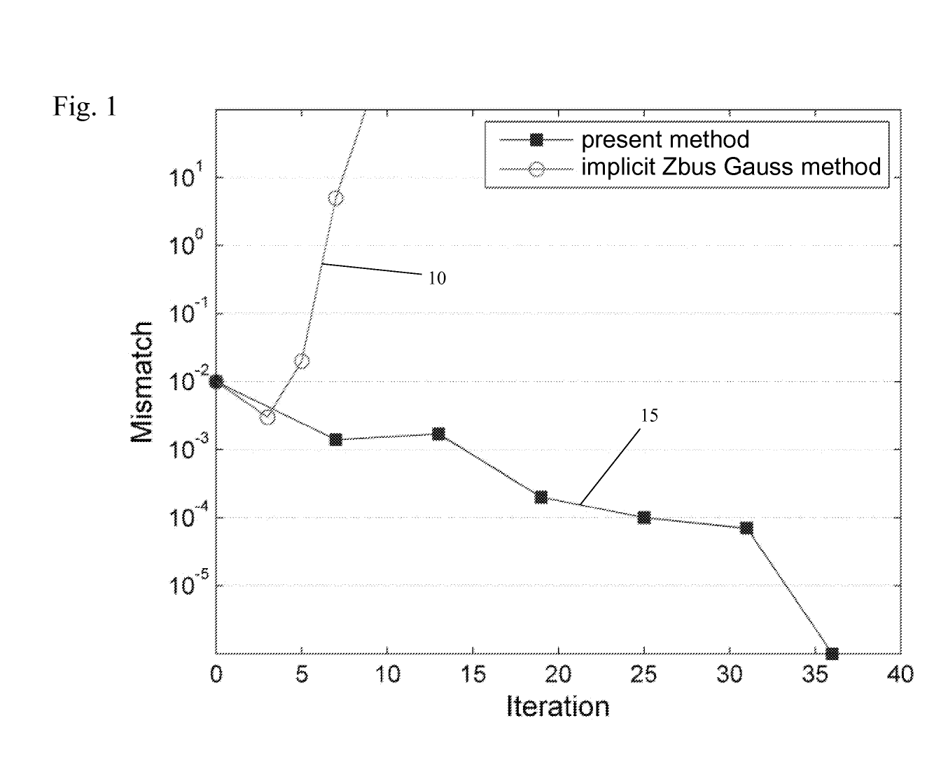

For the IEEE 13-bus system, a DG is connected to node #633 and this node is modeled as a P-V node. The prior art implicit Z-bus Gauss method 10 fails on this modified test system, while the present three-stage method 15 succeeds in obtaining the power flow solution as shown in FIG. 1.

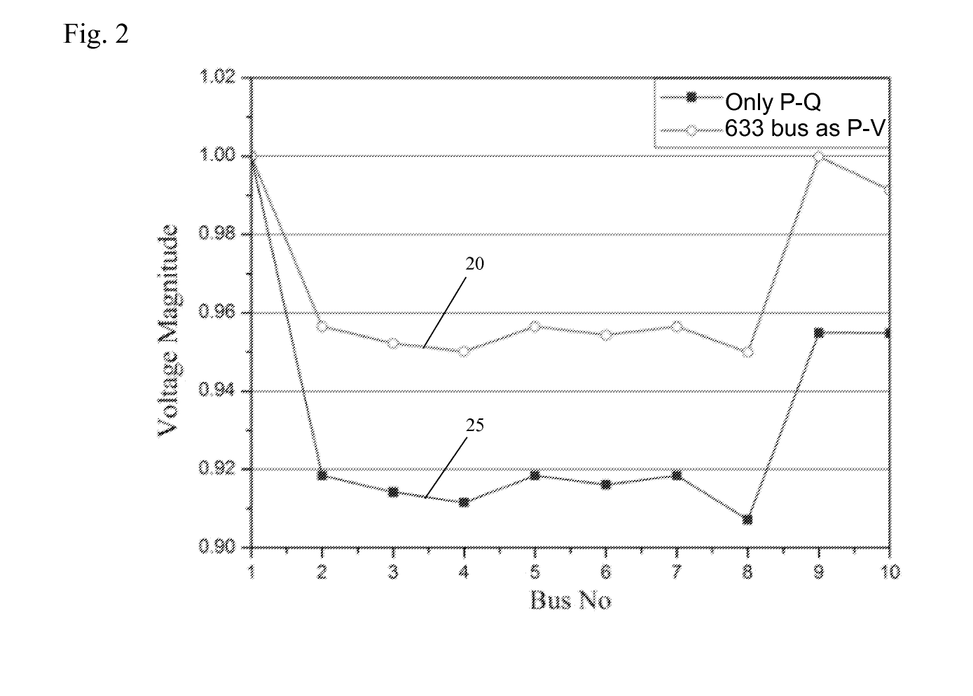

The result of the modified IEEE 13-node feeder obtained by the present three-stage method is presented in Table 1. The DG node #633 is now modeled as a P-V node. The specified positive sequence voltage at this node is 1.0 p.u. The power flow solution is summarized in Table 1 and a comparison between the voltage magnitudes of the power flow solution with a P-V model 20 and those with a P-Q model 25 is shown in FIG. 2.

TABLE 1
Power flow solution of IEEE 13-bus test system with DG
node #633 modeled as P-V node

| Bus | Phase A | | Phase B | | Phase C | |
|---|---|---|---|---|---|---|
| Name | Mag | Angle | Mag | Angle | Mag | Angle |
| 650 | 1.0000 | 0.00 | 1.0000 | −120.00 | 1.0000 | 120.00 |
| 680 | 0.9730 | 6.99 | 0.9993 | 123.57 | 0.9329 | 114.53 |
| 652 | 0.9694 | −6.99 | — | — | — | — |
| 675 | 0.9666 | −7.25 | 1.0015 | −123.75 | 0.9306 | 114.57 |
| 692 | 0.9730 | −6.99 | 0.9993 | −123.57 | 0.9329 | 114.53 |
| 611 | — | — | — | — | 0.9298 | 114.46 |
| 684 | 0.9715 | −7.02 | — | — | 0.9308 | 114.49 |
| 671 | 0.9730 | −7.00 | 0.9993 | −123.57 | 0.9329 | 114.53 |
| 634 | 0.9500 | −3.91 | 0.9499 | −123.96 | 0.9499 | 115.95 |
| 633 | 1.0000 | −3.91 | 1.0000 | −123.95 | 0.9999 | 115.95 |
| 646 | — | — | 0.9733 | −124.11 | 0.9907 | 116.36 |
| 645 | — | — | 0.9786 | −123.92 | 0.9899 | 116.37 |
| 632 | 0.9915 | −3.65 | 0.9921 | −123.58 | 0.9880 | 116.40 |

### IEEE 123-Bus System

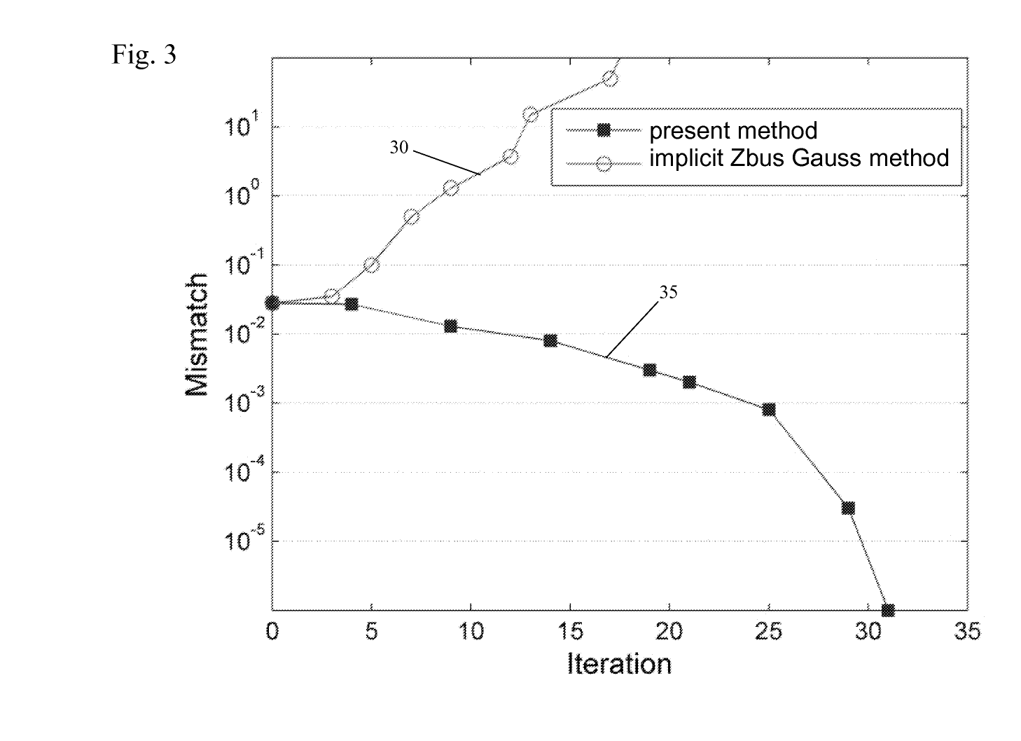

For the IEEE 123-bus system, a DG is connected to node #34 and this node is modeled as a P-V node. The prior art implicit Z-bus Gauss method 30 fails on this modified test system, while the present three-stage method 35 succeeds in obtaining a power flow solution as shown in FIG. 3.

### Industrial 1101-Node System

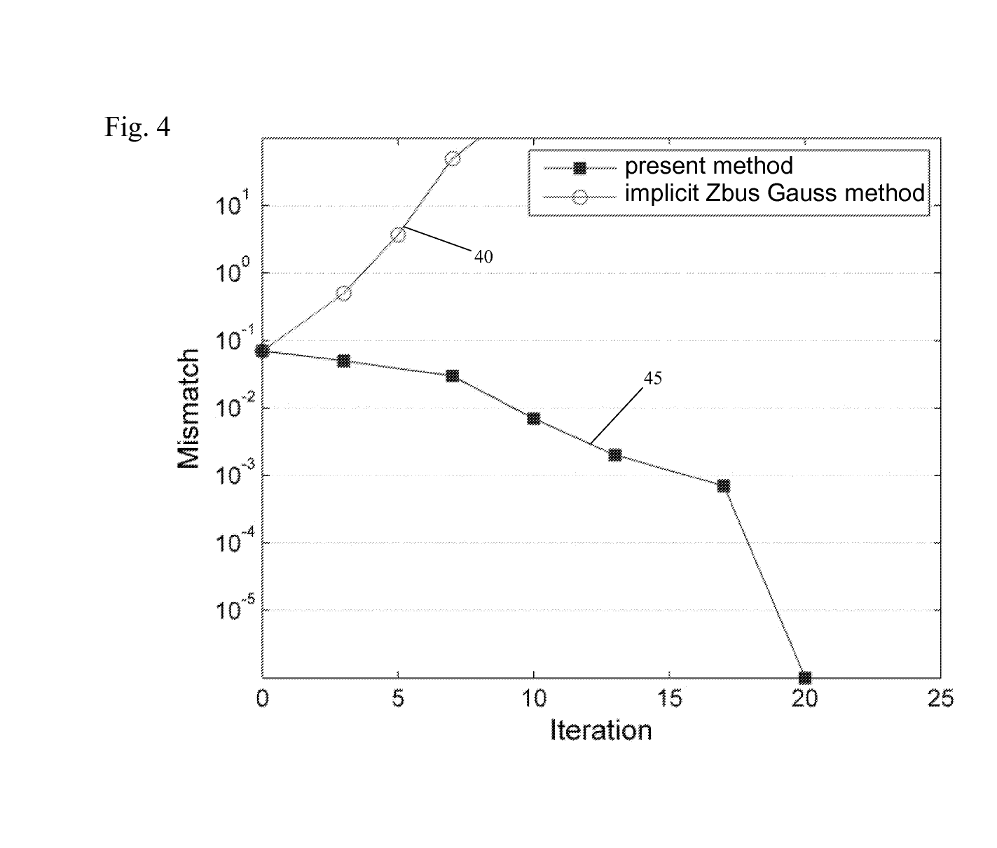

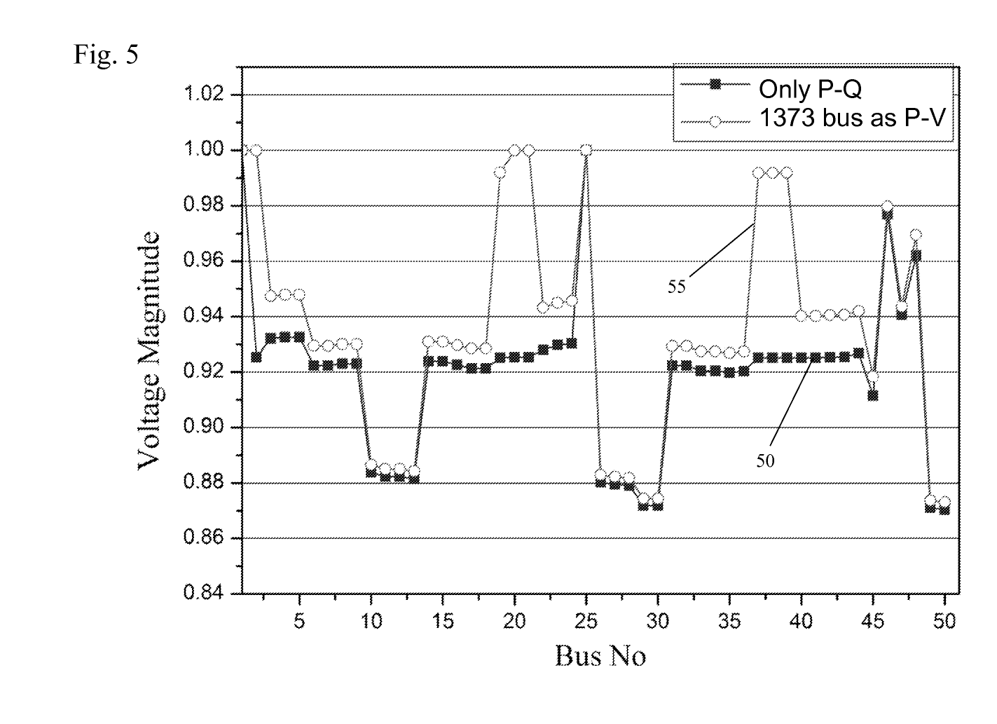

In a practical power distribution network with 1101 nodes, one DG is first connected to node #1373 and modeled as a P-V node. The prior art implicit Z-bus Gauss method 40 fails on this modified distribution network while the present three-stage method 45 succeeds in obtaining a power flow solution as shown in FIG. 4. A comparison of the voltage profiles of Phase A of the IEEE 1101-node System with the P-Q model 50 and with the P-V model 55 of one node in the system is shown in FIG. 5.

TABLE 2
Power Flow Solution of 1101-node net with Ten DGs

| | Voltage (p.u.) | | | Reactive Power (kVar) | | |
|---|---|---|---|---|---|---|
| PV ID | A | B | C | A | B | C |
| 1373 | 1.0000 | 1.0001 | 1.0000 | 2425.85 | 2647.56 | 2649.55 |
| 1296 | 0.9991 | 0.9990 | 0.9998 | 6216.22 | 7426.16 | 6879.81 |
| 1092 | 1.0001 | 1.0001 | 0.9998 | 228.81 | 500.527 | 564.63 |
| 1099 | 0.9998 | 1.0000 | 1.0001 | 1010.20 | 881.11 | −162.45 |
| 1138 | 1.0001 | 1.0001 | 1.0001 | 3318.30 | 3291.45 | 3314.00 |
| 1291 | — | 0.9990 | — | — | 2948.18 | — |
| 1230 | 1.0000 | 1.0000 | 1.0000 | 2102.14 | 1716.54 | 1620.99 |
| 1076 | 1.0000 | 1.0000 | 1.0000 | 2212.15 | 2723.47 | 1034.58 |
| 1222 | 1.0000 | 1.0000 | 1.0000 | 793.77 | −401.15 | 6718.64 |
| 1067 | 1.0000 | 1.0000 | 1.0000 | 5739.56 | 6777.14 | 671.83 |

To evaluate the robustness of the present method, ten DGs are connected to the 1101-node industrial distribution system. The specified positive sequence voltages at these nodes are 1.0 p.u. The present 3-stage method succeeds in obtaining a power flow solution as shown in Table 2.

### IEEE 8500-Bus System

### Case 1: One DG

One DG is connected to node #m1069148 of the 8500-bus and this node is modeled as a P-V node. The prior art implicit Z-bus Gauss method fails on this test system, while the present three-stage method succeeds in obtaining a power flow solution.

### Case 2: Five DGs

Five DGs are connected to the 8500-node industrial distribution system. The specified positive sequence voltages at these nodes are 1.0 p.u. The present three-stage method succeeds in obtaining a power flow solution as shown in Table 3.

TABLE 3
Power Flow Solution of 8500-node net with Five DGs

| | Voltage (p.u.) | | | Reactive Power (kVar) | | |
|---|---|---|---|---|---|---|
| PV ID | A | B | C | A | B | C |
| M1069148 | — | — | 1.0000 | — | — | 1667.04 |
| M1008753 | — | 1.0000 | — | — | 2609.53 | — |
| L2803199 | 0.9999 | 0.9999 | 0.9999 | 3290.35 | 2421.72 | 2070.18 |
| L3141390 | — | 1.0000 | — | — | 2.53 | — |
| M1142875 | 1.0000 | 1.0000 | 1.0000 | 2820.09 | 1247.97 | 1528.96 |

### Case 3: Ten DGs

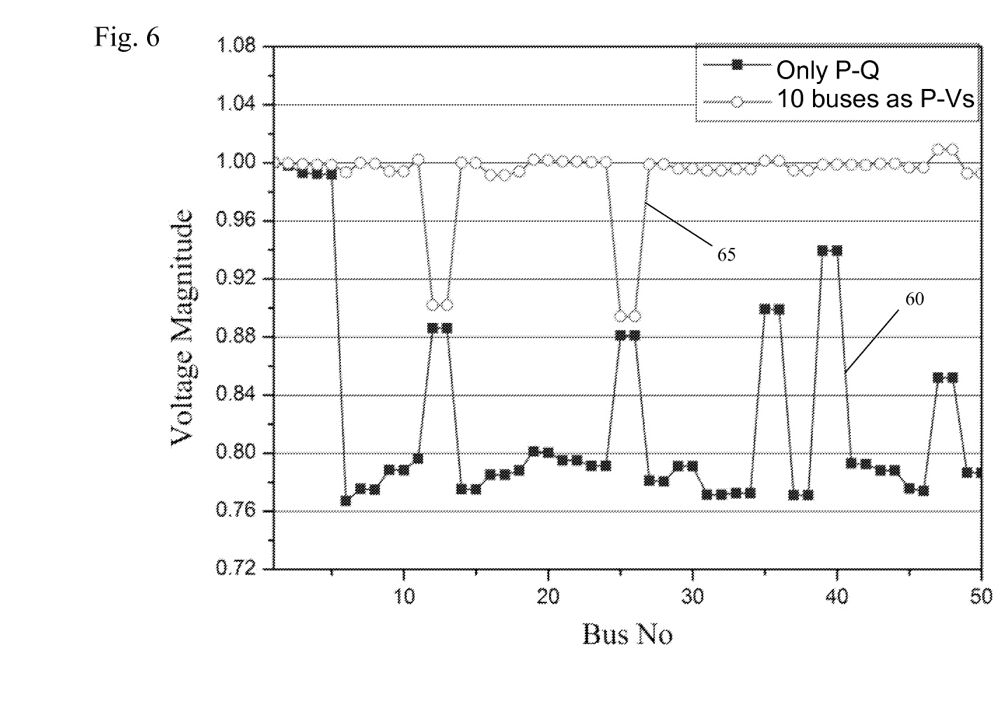

Ten DGs are connected to the 8500-node industrial distribution system. The specified positive sequence voltages at these nodes are 1.0 p.u. The present three-stage method succeeds in obtaining a power flow solution as shown in Table 4. A comparison of the voltage profiles of Phase A of the IEEE 8500-node System with the P-Q model 60 and with the P-V model 65 of ten nodes in the system is shown in FIG. 6.

TABLE 4
Power Flow Solution of 8500-node net with Ten DGs

| | Voltage (p.u.) | | | Reactive Power (kVar) | | |
|---|---|---|---|---|---|---|
| PV ID | A | B | C | A | B | C |
| M1069148 | — | — | 1.0000 | — | — | 1678.77 |
| M1008753 | — | 1.0000 | — | — | 2627.31 | — |
| L2803199 | 1.0000 | 1.0000 | 1.0000 | 451.72 | 761.19 | 599.50 |
| L3141390 | — | 1.0000 | — | — | 3.27 | — |
| M1142875 | 1.0000 | 1.0000 | 1.0000 | 734.22 | −165.58 | 291.51 |
| M1047423 | 1.0000 | — | — | 1536.42 | — | — |
| L2879089 | — | — | 1.0000 | — | — | 1054.83 |
| M1047750 | 1.0000 | — | — | 637.03 | — | — |
| L3101788 | 1.0000 | — | — | 864.15 | — | — |
| L3085398 | 0.9999 | 0.9999 | 0.9999 | 1821.29 | 3043.86 | 1756.71 |

### Homotopy-Enhanced Newton's Method

In some embodiments, a homotopy-enhanced Newton's method is used when Newton's method is used as the corrector in the homotopy procedure. From a practical viewpoint, any existing power flow method may be integrated into the present homotopy-enhanced method. In the present methodology, it is necessary to define an easy problem. Consider a 3-phase power flow equation with a constant impedance load model as an easy problem for Newton's method, in which the ZIP load model is replaced by the constant impedance model in Stage II.

A robust three-stage homotopy-enhanced Newton's method for power flow study for distribution networks with the load are modeled as ZIP combination model preferably proceeds as follows. Stage I aims to solve the power flow equations with the load being modeled as a ZIP combination model. It is known that Stage I may not converge, when the initial guess is far away from the solution or the solution is located close to a bifurcation point. The present method proceeds with Stage II and Stage III when Stage I of the 3-stage method is not able to solve the underlying problem. In Stage II, all of the load models are converted into a constant impedance model. A homotopy procedure is applied in Stage III so that the power flow equations, with the load being modeled as a ZIP combination model, are ‘eventually’ solved.
Stage I: Apply Newton's method as the power flow method to solve the power flow equations [1]. If the method converges to a solution, then stop. Otherwise, go to Stage II.
Stage II: Apply the power flow method of Stage Ito solve the simple power flow equations [2]. Let the solution be 0.7.
Stage III: Form the parameterized power flow equation [3] and apply the power flow method to iteratively solve the equation [3] starting from the power flow solution obtained in Stage II until the parameterized power flow equation [3] becomes the power flow equations [1] by varying the parameter value from zero to one.

The starting point in Stage III is the power flow solution obtained in Stage II, while the computational scheme for implementing Stage III is a continuation method.

### Stage I

1) Form Y_{bus} where only the constant impedance component of the load powers are incorporated into the diagonal elements of the nodal admittance matrix:

\dot{S}_{Li}^{Z}=αᵢ\dot{S}_{Li}⁰ y_{Li}=(\dot{S}_{Li}^{Z})*/(Vᵢ⁰)² i=1, 2, . . . , N [10]
2) Set the initial values of the voltages and phase angles for the P-Q buses and the phase angles for P-V buses.
3) Calculate the active and reactive powers, Pᵢ and Qᵢ for each load bus, which include the constant current and constant power components of the loads.
4) Calculate ΔPᵢ and ΔQᵢ at each bus.
5) Calculate the Jacobian matrix.
6) Solve the corrective equation for ΔVᵢ and Δθᵢ, and update the new values of voltages and phase angles.
7) If the predetermined tolerances in ΔVᵢ and Δθᵢ are achieved, terminate. Otherwise, go to step 3).

### Stage II

8) Construct an easy set of power flow equations in which all load models are converted into equivalent impedance loads. Computationally, the equivalent impedances of loads are incorporated into the diagonal elements of nodal admittance matrix:

\dot{S}_{Li}^{Z}=αᵢ\dot{S}_{Li}⁰+βᵢ\dot{S}_{Li}⁰+γᵢ\dot{S}_{Li}⁰ y_{Li}(\dot{S}_{Li}^{Z})*/(Vᵢ⁰)² i=1, 2, . . . , N [11]
9) Set the initial values of the voltages and phase angles for the P-Q buses and the phase angles for the P-V buses.
10) Apply Newton's method to solve the easy set of power flow equations until the predetermined tolerances in ΔVᵢ and Δθᵢ are satisfied. Then go to Stage III.

In Stage III, a homotopy function is constructed:

$${F}_{i} ( x ) = {S}_{Gi} - {S}_{Li}^{ZIP} - {\dot{V}}_{i} {\sum }_{j ∈ i}^{N} {Y}_{ij}^{*} {\dot{V}}_{j}^{*} = 0 \\ i = 1 , 2 , … , N \qquad [ 12 ]$$

in which loads are modeled as the original ZIP combination model,

$${\dot{S}}_{Li}^{ZIP ( k )} = {α}_{i} {\dot{S}}_{Li}^{0} {\vert {\dot{V}}_{i}^{( k )} \vert}^{2} + {β}_{i} {\dot{S}}_{Li}^{0} \frac{{\dot{V}}_{i}^{( k )}}{{\dot{V}}_{i}^{0}} + {γ}_{i} {\dot{S}}_{Li}^{0} \\ i = 1 , 2 , … , N \qquad [ 13 ]$$

and the set of easy power flow equations is:

$${G}_{i} ( x ) = {S}_{Gi} - {S}_{Li}^{Z} - {\dot{V}}_{i} {\sum }_{j ∈ i}^{N} {Y}_{ij}^{*} {\dot{V}}_{j}^{*} = 0 \\ i = 1 , 2 , … , N \qquad [ 14 ]$$

in which loads are modeled as the constant impedance model.

\dot{S}_{Li}^{Z(k)}=αᵢ\dot{S}_{Li}⁰|\dot{V}ᵢ^{(k)}|²+βᵢ\dot{S}_{Li}⁰|\dot{V}ᵢ^{(k)}|²+γᵢ\dot{S}_{Li}⁰|\dot{V}ᵢ^{(k)}|² i=1, 2, . . . , N [15]

The following homotopy function is then constructed:

Hᵢ(x,λ)=λFᵢ(x)+(1−λ)Gᵢ(x) i=1, 2, . . . , N [16]

By substitution of equations [13], [14], [15], and [16] into Hᵢ(x,λ),

$${H}_{i} ( x , λ ) = {F}_{i} ( x ) + ( 1 - λ ) [ {β}_{i} {\dot{S}}_{Li}^{0} ( \frac{{\dot{V}}_{i}^{( k )}}{{\dot{V}}_{i}^{0}} - {\vert {\dot{V}}_{i}^{( k )} \vert}^{2} ) + {γ}_{i} {\dot{S}}_{Li}^{0} ( 1 - {\vert {\dot{V}}_{i}^{( k )} \vert}^{2} ) ] \\ i = 1 , 2 , … , N \qquad [ 17 ]$$

A new parameter, arclength (s), is introduced. Both x and A are considered to be functions of the arclength parameter s:x=x(s), λ=λ(s)=xₙ₊₁. The step-size along the arclength s yields the following constraint:

$${\sum }_{i = 1}^{n} \{ {[ {x}_{i} - {x}_{i} ( s ) ]}^{2} \} + {( λ - λ ( s ) )}^{2} - {( Δ s )}^{2} = 0 \qquad [ 18 ]$$

If the Newton power flow in Stage II diverges, then decrease the system loading of the easy problem to construct another new easy problem and repeat step 8) to step 10) until the easy problem with the decreased system loading converges.

### Stage III

11) Determine a proper initial step length h=Δs, and compute the tangent direction vector (\vec{x}ₛ,\vec{λ}ₛ), which satisfies the following equation:

$$\{ \begin{matrix}{H}_{x} \frac{d x}{d s} + {H}_{{x}_{n + 1}} \frac{d {x}_{n + 1}}{d s} = 0 \\ {( \frac{d {x}_{1}}{d s} )}^{2} + {( \frac{d {x}_{2}}{d s} )}^{2} + … + {( \frac{d {x}_{n}}{d s} )}^{2} + {( \frac{d {x}_{n + 1}}{d s} )}^{2} = 1\end{matrix} \qquad [ 19 ]$$

12) If two points in the homotopy path were obtained, go to step 13). Otherwise, a predictor step is accomplished by integrating one step further in the prescribed tangent direction with the step size h:

$${\hat{x}}_{j}^{i + 1} = {x}_{j}^{i} + h \frac{d {x}_{j}}{d s} , \\ i = 1 , 2 , … , n + 1 \qquad [ 20 ]$$

13) A predictor step is accomplished by integrating one step further in the prescribed secant direction with the step size h:

(\hat{x}ⱼⁱ⁺¹)=(xⱼⁱ,λⱼⁱ)+h(xⱼⁱ−xⱼⁱ⁻¹,λⱼⁱ−λⱼⁱ⁻¹), i=1, 2, . . . , n+1 [21]
14) If the predicted \hat{λ}ⱼⁱ⁺¹ is very close to 1.0, set the predicted \hat{λ}ⱼⁱ⁺¹ to be 1.0 and go to step 15). Otherwise accomplish a corrector step by solving the augment equations:

$$\{ \begin{matrix}H ( x , λ ) = 0 \\ {\sum }_{i = 1}^{n} \{ {[ {x}_{i} - {x}_{i} ( s ) ]}^{2} \} + {( λ - λ ( s ) )}^{2} - {( Δ s )}^{2} = 0\end{matrix} \qquad [ 22 ]$$

15) Compute a corrector step by solving the following equation:

$$\{ \begin{matrix}H ( x , λ ) = 0 \\ λ = 1.0\end{matrix} \qquad [ 23 ]$$

16) If reach the target value 1.0, then a solution of F (x) is obtained, then terminate; otherwise, go to step 11).

Both Newton's method and the present homotopy-enhanced Newton's method were applied to the following standard test systems for illustrative purposes:

1) an IEEE 8,500-node test system

2) a practical 1101-node distribution network.

For each of the test systems, the prior art Newton's method fails in the cases that are close to the loading limit (i.e. Jacobian matrices close to singular), while the present homotopy-enhanced Newton's method succeeds in obtaining the power flow solution in all cases.

### IEEE 8500-Node System

Eight DGs are connected to the 8500-node distribution system. The specified positive sequence voltages at these nodes are 1.0 p.u. The present three-stage method succeeds in obtaining a power flow solution.

### Industrial 1101-Node System

In a practical power distribution network with 1101 nodes, four DGs are connected to node #1007, #1371, #1266 and #1008 and modeled as P-V nodes, while the constant impedance model is applied to all the loads. Unfortunately, the prior art Newton's method fails on this modified distribution network, while the present 3-stage method succeeds in obtaining a power flow solution.

Accordingly, it is to be understood that the embodiments of the invention herein described are merely illustrative of the application of the principles of the invention. Reference herein to details of the illustrated embodiments is not intended to limit the scope of the claims, which themselves recite those features regarded as essential to the invention.

What is claimed is:

1. A method of predicting a power flow solution in a distributed generation network comprising at least one distributed generator and at least one co-generator, the network being defined by a plurality of network nonlinear equations, the method comprising the steps of:
a) a computer applying an iterative method to the plurality of network nonlinear equations to achieve a divergence from the power flow solution to the plurality of network nonlinear equations;
b) the computer applying the iterative method to find a first solution to a plurality of simplified nonlinear equations homotopically related by parameterized power flow equations to the plurality of network nonlinear equations; and
c) the computer iteratively applying the iterative method to the parameterized power flow equations homotopically, starting with the first solution, to achieve the power flow solution to the plurality of network nonlinear equations.

2. The method of claim 1, wherein the at least one distributed generator and the at least one co-generator are modeled as P-V buses in step a).

3. The method of claim 1, wherein step c) comprises the substep of varying a parameter value from zero to one to convert the parameterized power flow equations to the plurality of network nonlinear equations.

4. The method of claim 1, wherein the iterative method is an Implicit Z-Bus Gauss method.

5. The method of claim 4, wherein, when the distributed generation network comprises a constant power device, step a) comprises the substeps of:
i) the computer establishing a nodal admittance matrix (Y_{bus}) for the distributed generation network;
ii) the computer partitioning the nodal admittance matrix into Y₁₁, Y₁₂, Y₁₃, Y₂₁, Y₂₂, Y₂₃, Y₃₁, Y₃₂, Y₃₃;
iii) the computer factoring
$$[ \begin{matrix}{Y}_{22} & {Y}_{23} \\ {Y}_{32} & {Y}_{33}\end{matrix} ]$$
into triangular factors L and U;
iv) the computer calculating a current (I₃) injected by constant (I) and constant (S) components based on a current value of V₃ and updating a current I₂ for a P-V node through bus equations:
$${Q}_{i} = Im \{ {V}_{i}^{* } {\sum }_{j = 1}^{m} {Y}_{ij} {V}_{j} \} and {I}_{i} = \frac{{P}_{i} - j {Q}_{i}}{{V}_{i}^{*}} ;$$
v) the computer solving
$$Ly = [ \begin{matrix}{I}_{2} \\ {I}_{3} ( {V}_{3} )\end{matrix} ] - [ \begin{matrix}{Y}_{21} \\ {Y}_{31}\end{matrix} ] {V}_{1}$$
for y via forward substitution;
vi) the computer solving
$$U [ \begin{matrix}{V}_{2} \\ {V}_{3}\end{matrix} ] = y$$
for
$$[ \begin{matrix}{V}_{2} \\ {V}_{3}\end{matrix} ]$$
via backward substitution and maintaining a voltage magnitude at a value
$${V}_{i} = \frac{{V}_{i}}{\vert {V}_{i} \vert} \cdot \vert {V}_{( spec )} \vert$$
for a P-V node; and
vii) the computer iteratively repeating substep iii) through substep vi) until a change in
$$[ \begin{matrix}{V}_{2} \\ {V}_{3}\end{matrix} ]$$
is less than a predetermined tolerance.

6. The method of claim 5, wherein step b) comprises the substeps of:
viii) the computer factoring
$$[ \begin{matrix}{Y}_{22} & {Y}_{23} \\ {Y}_{32} & {Y}_{33}\end{matrix} ]$$
into triangular factors L and U;
ix) the computer calculating a current (I₃) injected by constant (I) and constant (S) components based on a current value of V₃;
x) the computer solving
$$Ly = [ \begin{matrix}{I}_{2} \\ {I}_{3} ( {V}_{3} )\end{matrix} ] - [ \begin{matrix}{Y}_{21} \\ {Y}_{31}\end{matrix} ] {V}_{1}$$
for y via forward substitution;
xi) the computer solving
$$U [ \begin{matrix}{V}_{2} \\ {V}_{3}\end{matrix} ] = y$$
for
$$[ \begin{matrix}{V}_{2} \\ {V}_{3}\end{matrix} ]$$
via backward substitution; and
xii) the computer iteratively repeating substep ix) through substep xi) until a change in
$$[ \begin{matrix}{V}_{2} \\ {V}_{3}\end{matrix} ]$$
is less than a predetermined tolerance.

7. The method of claim 6, wherein step c) comprises the substeps of:
xiii) the computer determining a partition (Δλ) and using a value for V_{2(P-Q)} obtained in step b) as an initial guess;
xiv) the computer setting λ and saving a converged voltage and a reactive power and, if |V−V_{(spec)}| is less than a predetermined tolerance, the computer outputting the power flow solution and terminating the method;
xv) the computer calculating a current injected for a bus modeled as a P-V bus by a parameterized vector: I₂=λI_{2(spec)}+(1−λ)I_{2(P-Q)},
wherein
$${I}_{2 ( P - Q )} = \frac{P - j {Q}_{( P - Q )}}{{V}_{2 ( P - Q )}^{*}} and {I}_{2 ( spec )} = \frac{P - j {Q}^{′}}{{V}_{2 ( spec )}^{*}}$$
and
for I_{2(spec)}, calculating Q′ by
$${S}_{i}^{′} = P + j {Q}^{′} = {V}_{i} {\sum }_{j ∈ i} {Y}_{ij}^{*} {V}_{j}^{*} ;$$
xvi) the computer solving
$$Ly = [ \begin{matrix}{I}_{2} \\ {I}_{3} ( {V}_{3} )\end{matrix} ] - [ \begin{matrix}{Y}_{21} \\ {Y}_{31}\end{matrix} ] {V}_{1}$$
for y via forward substitution;
xvii) the computer solving
$$U [ \begin{matrix}{V}_{2} \\ {V}_{3}\end{matrix} ] = y$$
for
$$[ \begin{matrix}{V}_{2} \\ {V}_{3}\end{matrix} ]$$
via backward substitution; and
xviii) the computer proceeding to substep xiv) if a change in
$$[ \begin{matrix}{V}_{2} \\ {V}_{3}\end{matrix} ]$$
is less than a predetermined tolerance, otherwise the computer updating λ, setting voltage vector V₂=λV_{2(spec)}+(1−λ)V₂, and proceeding to substep xv).

8. The method of claim 1, wherein the iterative method is Newton's method.

9. The method of claim 8, wherein step a) comprises the substeps of:
i) the computer establishing a nodal admittance matrix (Y_{bus}) for the distributed generation network, wherein only a single constant impedance component of each load power is incorporated into diagonal elements of the nodal admittance matrix (\dot{S}_{Li}^{Z}=αᵢ\dot{S}_{Li}⁰ y_{Li}=(\dot{S}_{Li}^{Z})*/(Vᵢ⁰)² i=1, 2, . . . , N);
ii) the computer setting initial values of voltages and phase angles for P-Q buses and phase angles for P-V buses;
iii) the computer calculating active powers (Pᵢ) and reactive powers (Qᵢ) for each load bus, including a constant current component and a constant power component of each load;
iv) the computer calculating ΔPᵢ and ΔQᵢ at each bus;
v) the computer calculating a Jacobian matrix;
vi) the computer solving corrective equations for ΔVᵢ and Δθᵢ, and updating new values of voltages and phase angles; and
vii) the computer iteratively repeating substep iii) through substep vi) until ΔVᵢ and Δθᵢ are less than predetermined tolerances.

10. The method of claim 9, wherein step b) comprises the substeps of:
viii) the computer constructing the plurality of simplified nonlinear equations, wherein load models are converted into equivalent impedance loads, the equivalent impedance loads being incorporated into diagonal elements of the nodal admittance matrix:
\dot{S}_{Li}^{Z}=αᵢ\dot{S}_{Li}⁰+βᵢ\dot{S}_{Li}⁰+γᵢ\dot{S}_{Li}⁰ y_{Li}=(\dot{S}_{Li}^{Z})*/(Vᵢ⁰)² i=1, 2, . . . , N;
ix) the computer setting initial values of the voltages and phase angles for P-Q buses and phase angles for P-V buses; and
x) the computer iteratively applying Newton's method to solve the plurality of simplified nonlinear equations until ΔVᵢ and Δθᵢ are less than predetermined tolerances.

11. The method of claim 10, wherein step c) comprises the substeps of:
xi) the computer determining an initial step length (h=Δs) and computing a tangent direction vector (\vec{x}ₛ, \vec{λ}ₛ) satisfying:
$$\{ \begin{matrix}{H}_{x} \frac{d x}{d s} + {H}_{{x}_{n + 1}} \frac{d {x}_{n + 1}}{d s} = 0 \\ {( \frac{d {x}_{1}}{d s} )}^{2} + {( \frac{d {x}_{2}}{d s} )}^{2} + … + {( \frac{d {x}_{n}}{d s} )}^{2} + {( \frac{d {x}_{n + 1}}{d s} )}^{2} = 1\end{matrix} ;$$
xii) the computer proceeding to substep xiii) if two points in a homotopy path are obtained in substep xi) or otherwise the computer calculating a first predictor step by integrating one step further in a direction of the tangent direction vector with step size h:
$${\hat{x}}_{j}^{i + 1} = {x}_{j}^{i} + h \frac{d {x}_{j}}{d s} ,$$
i=1, 2, . . . , n+1 and proceeding to substep xiv);
xiii) the computer calculating the first predictor step by integrating one step further in a secant direction with step size h:
(\hat{x}ⱼⁱ⁺¹,\hat{λ}ⱼⁱ⁺¹)=(xⱼⁱ,λⱼⁱ)+h(xⱼⁱ−xⱼⁱ⁻¹,λⱼⁱ−λⱼⁱ⁻¹), i=1, 2, . . . , n+1;
xiv) the computer setting predicted \hat{λ}ⱼⁱ⁺¹ to 1.0 and proceeding to substep xv) if predicted |\hat{λ}ⱼⁱ⁺¹−1.0| is less than a predetermined tolerance, otherwise the computer calculating a second corrector step by solving:
$$\{ \begin{matrix}H ( x , λ ) = 0 \\ {\sum }_{i = 1}^{n} \{ {[ {x}_{i} - {x}_{i} ( s ) ]}^{2} \} + {( λ - λ ( s ) )}^{2} - {( Δ s )}^{2} = 0\end{matrix} ;$$
xv) the computer calculating a third corrector step by solving:
$$\{ \begin{matrix}H ( x , λ ) = 0 \\ λ = 1.0\end{matrix} ;$$
and
xvi) the computer outputting the power flow solution if λ equals 1.0, otherwise, the computer proceeding to substep xi).

12. A method of predicting a power flow solution in a distributed generation network comprising at least one distributed generator and at least one co-generator, the network being defined by a plurality of network nonlinear equations, the method comprising the steps of:
a) the computer applying an iterative method to find a first solution to a plurality of simplified nonlinear equations homotopically related by parameterized power flow equations to the plurality of network nonlinear equations; and
b) the computer iteratively applying the iterative method to the parameterized power flow equations homotopically, starting with the first solution, to achieve the power flow solution to the plurality of network nonlinear equations.

13. The method of claim 12, wherein step b) comprises the substep of varying a parameter value from zero to one to convert the parameterized power flow equations to the plurality of network nonlinear equations.

14. The method of claim 12, wherein the iterative method is an Implicit Z-Bus Gauss method.

15. The method of claim 14, wherein, when the distributed generation network comprises a constant power device, step a) comprises the substeps of:
i) the computer establishing a nodal admittance matrix (Y_{bus}) for the distributed generation network;
ii) the computer partitioning the nodal admittance matrix into Y₁₁, Y₁₂, Y₁₃, Y₂₁, Y₂₂, Y₂₃, Y₃₁, Y₃₂, Y₃₃;
iii) the computer factoring
$$[ \begin{matrix}{Y}_{22} & {Y}_{23} \\ {Y}_{32} & {Y}_{33}\end{matrix} ]$$
into triangular factors L and U;
iv) the computer calculating a current (I₃) injected by constant (I) and constant (S) components based on a current value of V₃;
v) the computer solving
$$Ly = [ \begin{matrix}{I}_{2} \\ {I}_{3} ( {V}_{3} )\end{matrix} ] - [ \begin{matrix}{Y}_{21} \\ {Y}_{31}\end{matrix} ] {V}_{1}$$
for y via forward substitution;
vi) the computer solving
$$U [ \begin{matrix}{V}_{2} \\ {V}_{3}\end{matrix} ] = y$$
for
$$[ \begin{matrix}{V}_{2} \\ {V}_{3}\end{matrix} ]$$
via backward substitution; and
vii) the computer iteratively repeating substep iv) through substep vi) until a change in
$$[ \begin{matrix}{V}_{2} \\ {V}_{3}\end{matrix} ]$$
is less than a predetermined tolerance.

16. The method of claim 15, wherein step b) comprises the substeps of:
viii) the computer determining a partition (Δλ) and using a value for V_{2(P-Q)} obtained in step b) as an initial guess;
ix) the computer setting λ and saving a converged voltage and a reactive power and, if |V−V_{(spec)}| is less than a predetermined tolerance, the computer outputting the power flow solution and terminating the method;
x) the computer calculating a current injected for a bus modeled as a P-V bus by a parameterized vector: I₂=λI_{2(spec)}+(1−λ)I_{2(P-Q)},
wherein
$${I}_{2 ( P - Q )} = \frac{P - j {Q}_{( P - Q )}}{{V}_{2 ( P - Q )}^{*}}$$
$$and$$
$${I}_{2 ( spec )} = \frac{P - j {Q}^{′}}{{V}_{2 ( spec )}^{*}}$$
and
for I_{2(spec)}, calculating Q′ by
$${S}_{i}^{′} = P + j {Q}^{′} = {V}_{i} {\sum }_{j ∈ i} {Y}_{ij}^{*} {V}_{j}^{*} ;$$
xi) the computer solving
$$Ly = [ \begin{matrix}{I}_{2} \\ {I}_{3} ( {V}_{3} )\end{matrix} ] - [ \begin{matrix}{Y}_{21} \\ {Y}_{31}\end{matrix} ] {V}_{1}$$
for y via forward substitution;
xii) the computer solving
$$U [ \begin{matrix}{V}_{2} \\ {V}_{3}\end{matrix} ] = y$$
for
$$[ \begin{matrix}{V}_{2} \\ {V}_{3}\end{matrix} ]$$
via backward substitution; and
xiii) the computer proceeding to substep ix) if a change in
$$[ \begin{matrix}{V}_{2} \\ {V}_{3}\end{matrix} ]$$
is less than a predetermined tolerance, otherwise the computer updating λ, setting voltage vector V₂=λV_{2(spec)}+(1−λ)V₂, and proceeding to substep x).

17. The method of claim 12, wherein the iterative method is Newton's method.

18. The method of claim 17, wherein step a) comprises the substeps of:
i) the computer constructing the plurality of simplified nonlinear equations, wherein load models are converted into equivalent impedance loads, the equivalent impedance loads being incorporated into diagonal elements of the nodal admittance matrix:
\dot{S}_{Li}^{Z}=αᵢ\dot{S}_{Li}⁰+βᵢ\dot{S}_{Li}⁰+γᵢ\dot{S}_{Li}⁰ y_{Li}=(\dot{S}_{Li}^{Z})*/(Vᵢ⁰)² i=1, 2, . . . , N;
ii) the computer setting initial values of the voltages and phase angles for P-Q buses and phase angles for P-V buses; and
iii) the computer iteratively applying Newton's method to solve the plurality of simplified nonlinear equations until ΔVᵢ and Δθᵢ are less than predetermined tolerances.

19. The method of claim 18, wherein step b) comprises the substeps of:
iv) the computer determining an initial step length (h=Δs) and computing a tangent direction vector (\vec{x}ₛ,\vec{λ}ₛ) satisfying:
$$\{ \begin{matrix}{H}_{x} \frac{d x}{d s} + {H}_{{x}_{n + 1}} \frac{d {x}_{n + 1}}{d s} = 0 \\ {( \frac{d {x}_{1}}{d s} )}^{2} + {( \frac{d {x}_{2}}{d s} )}^{2} + … + {( \frac{d {x}_{n}}{d s} )}^{2} + {( \frac{d {x}_{n + 1}}{d s} )}^{2} = 1\end{matrix} ;$$
v) the computer proceeding to substep vi) if two points in a homotopy path are obtained in substep iv) or otherwise the computer calculating a first predictor step by integrating one step further in a direction of the tangent direction vector with step size h:
$${\hat{x}}_{j}^{i + 1} = {x}_{j}^{i} + h \frac{d {x}_{j}}{d s} ,$$
i=1, 2, . . . , n+1 and proceeding to substep vii);
vi) the computer calculating the first predictor step by integrating one step further in a secant direction with step size h:
(\hat{x}ⱼⁱ⁺¹,\hat{λ}ⱼⁱ⁺¹)=(xⱼⁱ,λⱼⁱ)+h(xⱼⁱ−xⱼⁱ⁻¹,λⱼⁱ−λⱼⁱ⁻¹), i=1, 2, . . . , n+1;
vii) the computer setting predicted \hat{λ}ⱼⁱ⁺¹ to 1.0 and proceeding to substep xv) if predicted |\hat{λ}ⱼⁱ⁺¹−1.0| is less than a predetermined tolerance, otherwise the computer calculating a second corrector step by solving:
$$\{ \begin{matrix}H ( x , λ ) = 0 \\ {\sum }_{i = 1}^{n} \{ {[ {x}_{i} - {x}_{i} ( s ) ]}^{2} \} + {( λ - λ ( s ) )}^{2} - {( Δ s )}^{2} = 0\end{matrix} ;$$
viii) the computer calculating a third corrector step by solving:
$$\{ \begin{matrix}H ( x , λ ) = 0 \\ λ = 1.0\end{matrix} ;$$
and
ix) the computer outputting the power flow solution if λ equals 1.0, otherwise, the computer proceeding to substep iv).
